(19) United States
(12) Patent Application Publication
(10) Pub. No.: US 2025/0008643 A1
(43) Pub. Date: Jan. 2, 2025

(54) INTEGRATED ELECTRODE AND CABLE STRUCTURE

(71) Applicant: Board of Regents, The University of Texas System, Austin, TX (US)

(72) Inventors: Negar Geramifard, Oakland, CA (US); Stuart Cogan, Dallas, TX (US)

(21) Appl. No.: 18/757,031

(22) Filed: Jun. 27, 2024

Related U.S. Application Data
(60) Provisional application No. 63/510,583, filed on Jun. 27, 2023.

(51) Int. Cl. H05K 1/02; H05K 1/03; H05K 3/06

(52) U.S. Cl. CPC H05K 1/0296; H05K 1/0353; H05K 3/06; H05K 2201/0154

(57) ABSTRACT

An electrode including: an electrode body including a length down a central axis, where the electrode body includes a flexible, stretchable ribbon cable portion including at least one trace including a conductive material, at least one stiff and penetrable electrode shank site portion including at least one trace including a conductive material, and a transition portion between the ribbon cable portion and the at least one stiff and penetrable electrode shank site portion.

### CROSS REFERENCE TO RELATED APPLICATION

This application claims priority under 35 U.S.C. § 119(e) to U.S. Patent Application No. 63/510,583 entitled “INTEGRATED ELECTRODE AND CABLE STRUCTURE,” by Negar GERAMIFARD et al., filed Jun. 27, 2023, which is assigned to the current assignee hereof and incorporated herein by reference in its entirety.

### STATEMENT OF GOVERNMENT SUPPORT

This invention was made with government support under grant no. R01 NS104344 awarded by the National Institutes of Health. The government has certain rights in the invention.

### FIELD OF THE DISCLOSURE

The present disclosure relates to integrated ribbon cable microelectrode array (MEA) hybrids and particularly integrated ribbon cable microelectrode array hybrids implantable as medical devices.

### RELATED ART

Although ribbon cables are great substitutes for wire interconnects by providing a wider range of motion such as flexibility or extensibility, the number of channels in microelectrode arrays is still restricted to the resolution of soldering and wire bonding processes, prohibiting to increase the electrode channel count without compromising the size of the MEA backend. Therefore, there continues to be a need for improved ribbon cables integrating MEAs.

### BRIEF DESCRIPTION OF THE DRAWINGS

Embodiments are illustrated by way of example and are not limited in the accompanying figures.

FIG. 1A includes a schematic view of an integrated ribbon cable MEA with flexible ribbon site and stiff and penetrable shank sites in accordance with an embodiment;

FIG. 1B includes a cross-sectional view of an integrated ribbon cable MEA with flexible ribbon site and stiff and penetrable shank sites in accordance with an embodiment;

FIG. 2A includes a top view of a metal trace with a transitional step from a flexible ribbon site to a stiff shank site for an integrated ribbon cable MEA in accordance with an embodiment;

FIG. 2B includes a top view of a metal trace with a transitional step from a flexible ribbon site to a stiff shank site for an integrated ribbon cable MEA in accordance with an embodiment;

FIG. 2C includes a cross-sectional view of a metal trace with a transitional step from a flexible ribbon site to a stiff shank site for an integrated ribbon cable MEA in accordance with an embodiment;

FIG. 2D includes a IV curve of a metal trace with a transitional step from a flexible ribbon site to a stiff shank site for an integrated ribbon cable MEA according to the embodiment;

FIG. 3 includes a schematic view of an integrated ribbon cable MEA with flexible ribbon site and stiff and penetrable shank sites with 16-32 channels in accordance with an embodiment;

FIG. 4-1 includes a schematic view of an integrated ribbon cable MEA with flexible ribbon site and stiff and penetrable shank sites during fabrication step 1 in accordance with an embodiment;

FIG. 4-2 includes a schematic view of an integrated ribbon cable MEA with flexible ribbon site and stiff and penetrable shank sites during fabrication step 2 in accordance with an embodiment;

FIG. 4-3 includes a schematic view of an integrated ribbon cable MEA with flexible ribbon site and stiff and penetrable shank sites during fabrication step 3 in accordance with an embodiment;

FIG. 4-4 includes a schematic view of an integrated ribbon cable MEA with flexible ribbon site and stiff and penetrable shank sites during fabrication step 4 in accordance with an embodiment;

FIG. 4-5 includes a schematic view of an integrated ribbon cable MEA with flexible ribbon site and stiff and penetrable shank sites during fabrication step 5 in accordance with an embodiment;

FIG. 4-6 includes a schematic view of an integrated ribbon cable MEA with flexible ribbon site and stiff and penetrable shank sites during fabrication step 6 in accordance with an embodiment;

FIG. 4-7 includes a schematic view of an integrated ribbon cable MEA with flexible ribbon site and stiff and penetrable shank sites during fabrication step 7 in accordance with an embodiment;

FIG. 4-8 includes a schematic view of an integrated ribbon cable MEA with flexible ribbon site and stiff and penetrable shank sites during fabrication step 8 in accordance with an embodiment;

FIG. 4-9 includes a schematic view of an integrated ribbon cable MEA with flexible ribbon site and stiff and penetrable shank sites during fabrication step 9 in accordance with an embodiment;

FIG. 5A includes a zoomed-in top view SEM image of an integrated ribbon cable MEA with flexible ribbon site and stiff and penetrable shank sites in accordance with an embodiment;

FIG. 5B includes a zoomed-in top view SEM image of an integrated ribbon cable MEA with flexible ribbon site and stiff and penetrable shank sites in accordance with an embodiment;

FIG. 5C includes a zoomed-in top view SEM image of an integrated ribbon cable MEA with flexible ribbon site and stiff and penetrable shank sites in accordance with an embodiment;

FIG. 5D includes a zoomed-in top view SEM image of an integrated ribbon cable MEA with flexible ribbon site and stiff and penetrable shank sites in accordance with an embodiment; and

FIG. 5E includes a zoomed-in top view SEM image of an integrated ribbon cable MEA with flexible ribbon site and stiff and penetrable shank sites in accordance with an embodiment.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single embodiment is described herein, more than one embodiment may be used in place of a single embodiment. Similarly, where more than one embodiment is described herein, a single embodiment may be substituted for that more than one embodiment.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the electrode and ribbon cable arts.

### A Summary of the Motivation for an Integrated UMEA-Ribbon Cable

Integrating flexible interconnects with UMEAs (ultra-micro electrode array) allows for the realization of high-density neural structures with a high number of channel counts while minimizing tissue displacement by reducing tethering force due to the heaviness and bulkiness of interconnects in the subdural space. We hypothesized that integrating interconnects and UME array would provide a reliable connection between UME arrays and external electrical hardware. We developed integrated ribbon-UMEAs using the photolithography process, maintaining flexibility and extensibility of interconnects while permitting insertion of 2D or 3D UMEA into rat cortex without any guide or support.

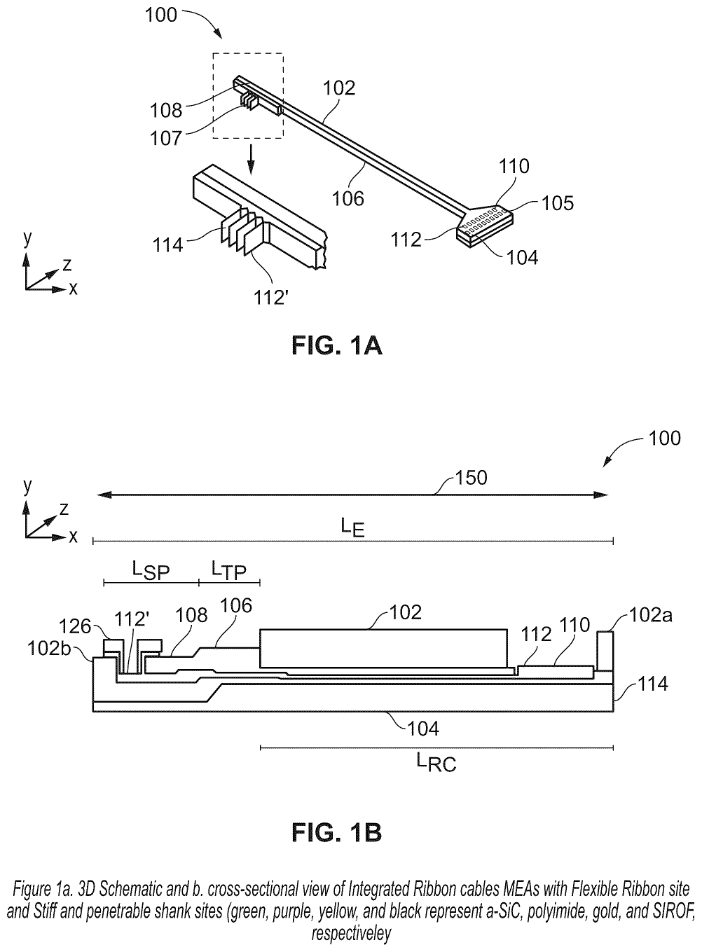

Integrated Ribbon-UMEA consists of two main parts: (1) Flexible/stretchable Ribbon site with polyimide as the base material and (2) stiff and penetrable shank sites with a-SiC as the base substrate. A silicon wafer served as the substrate. A schematic view of the structure is shown below in FIG. 1.

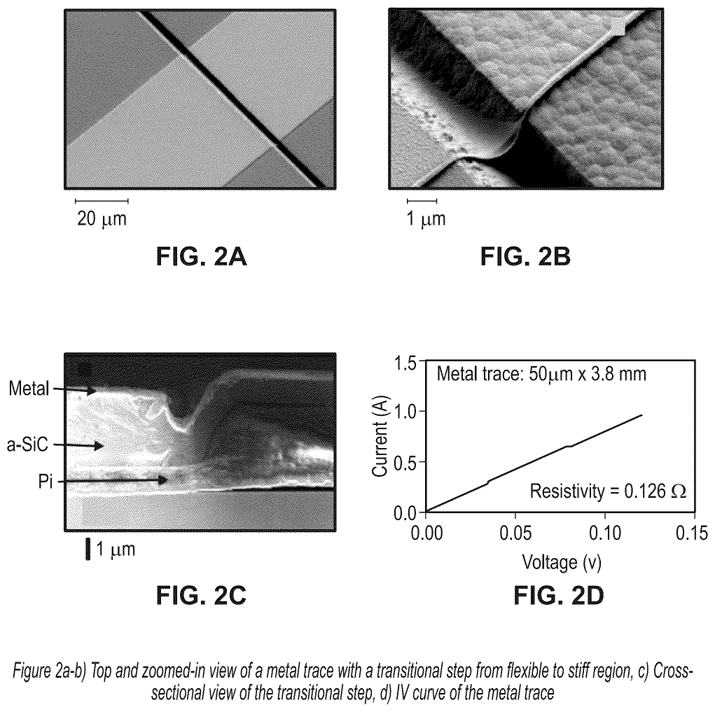

We firstly assessed the reliability of conductive traces in the integrated Ribbon-MEAs. A high step in the cross-section of the structure may impair the continuity in the metal traces, and this can happen during the transition from the flexible region to the stiff structure after the etching process. The conductance of metal traces was obtained from the IV measurement in some test structures with metal strips. Scanning electrode microscopy (SEM) images and electrical measurements suggest the integrity of metal traces in the entire structure (FIG. 2). Hence, based on the reliability of metal traces, the fabrication process of integrated-Ribbon-MEAs was developed.

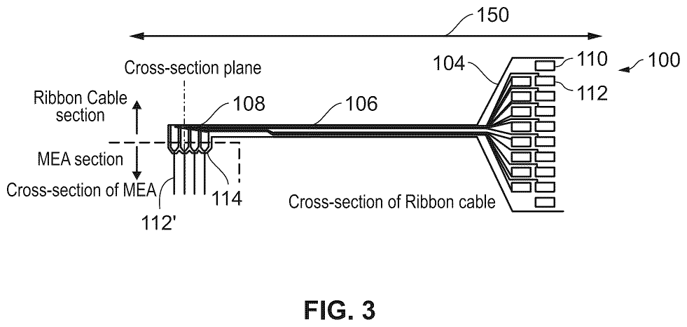

We designed and developed a photolithography process to provide stiff-penetrable MEAs integrated into hybrid a-SiC-PI ribbon cables in various geometries, including the design of UMEAs with 16 and 32 electrodes. Each array includes four to eight shanks in which four electrodes are placed along the individual ones, providing neural recording and stimulation in various depths of cortical column, unlike carbon fiber UMEAs or UTAH arrays which only provide electrodes at the tip of each probe. One highlighted innovation of the current work is a design that enables us to have 3D UMEAs built from two or more planar UMEAs integrated into flexible and extensible interconnects as shown in FIG. 3. Fabrication process steps include PI coating, a-SiC deposition, metallization, etching and several photo lithography processes.

### A Summary of the Fabrication Process for an Integrated UMEA-Ribbon Cable

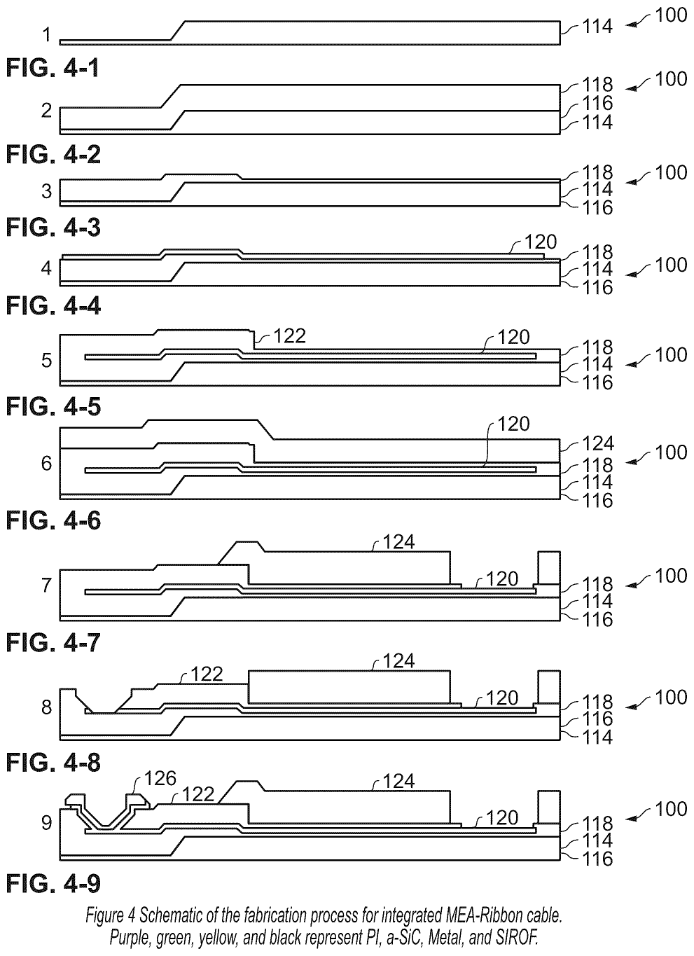

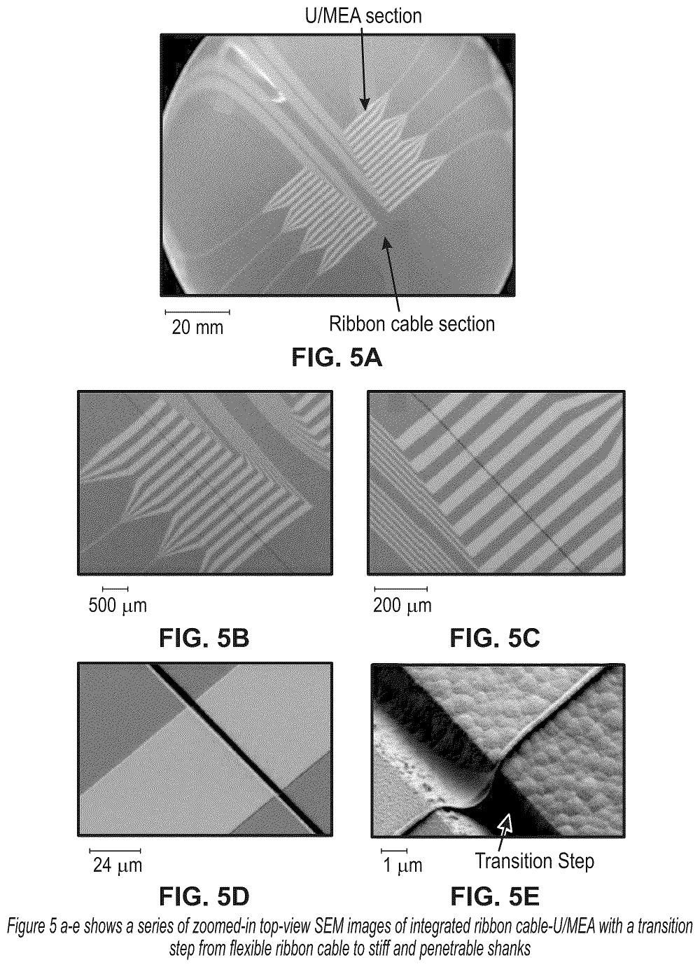

FIGS. 4-1 to 4-9 illustrate a step-by-step process for fabricating an integrated UMEA-ribbon cable in accordance with an embodiment. The fabrication process outlined below is exemplary and not intended to be limited by materials or order or process. FIG. 4-1 illustrates PI coating and curing (thickness of 4 m) and later etching partially (2.5 μm) PI from U/MEA section. FIG. 4-2 illustrates Deposition of a-SiC film using PECVD system with a thickness of 3 μm. FIG. 4-3 illustrates Partial etching (2.5 μm) of a-SiC from the ribbon cable section (to have a smooth transition, we modified the process to have a large lateral and an isotropic etching profile). FIG. 4-4 illustrates Metal patterning using the photolithography process and metal deposition were done to define the conductive traces. FIG. 4-5 illustrates a second layer of a-SiC with thickness of 3 m was deposited using PECVD system and later 2.5 m of a-SiC was etched from the ribbon cable section to reduce the thickness of a-SiC and increase the flexibility of ribbon cables. FIG. 4-6 illustrates a second layer of PI film was coated. FIG. 4-7 illustrates PI was fully etched from U/MEA section and only from bond pad areas on the ribbon section. FIG. 4-8 illustrates a-SiC was etched to open the electrode site via bond pads to access the gold traces encapsulated in a-SiC and PI. FIG. 4-9 illustrates electrode film was patterned, and electrode material was deposited by a sputtering system followed by a lift-off process. Photolithography process and dry etching were used to define the device shapes and later released after being soaked in DIW.

FIGS. 5A-5E illustrate a series of a zoomed-in top view SEM images of an integrated ribbon cable MEA with flexible ribbon site and stiff and penetrable shank sites in accordance with an embodiment. As shown the transition step between the flexible ribbon cable to the stiff and penetrable shank may be visible.

### Electrochemical Characteristics for an Integrated UMEA-Ribbon Cable

Electrochemical measurement performance of integrated UMEA-ribbon cable is shown in FIG. 6. A 200 μm2 of SIROF electrode film provides a similar charge storage capacity of CSCc of 40-55 mC/cm2 and impedance of around 50 kΩ at 1 kHz identical to reported values common in the art for ribbon cables.

Referring back to FIGS. 1A-1B, an electrode 100 is shown according to a number of embodiments. In a number of embodiments, the electrode 100 may be implantable upon a biological substrate, as described herein. The electrode 100 may include a electrode body 102 in a longitudinal (x), lateral (y) and transversal (z) dimensional axis system comprising a length, L_{E}, between a first axial end 102a and a second axial end 102b down a central longitudinal (x) axis 150. The electrode body 102 may include at least one flexible, stretchable ribbon cable portion 104 having a length, L_{E}, along at least a portion of the length, L_{E}, of the electrode body 102. The at least one flexible, stretchable ribbon cable portion 104 can be configured in conformance with overall interconnect geometry of a desired application. In a number of embodiments, the flexible, stretchable ribbon cable portion 104 may include a trace end 112 including an electrically conductive material. The electrode body 102 may further include at least one stiff and penetrable electrode shank site portion 108 having a length, L_{SP}, along at least a portion of the length, L_{E}, of the electrode body 102. The at least one stiff and penetrable electrode shank site portion 108 can be configured in conformance with overall interconnect geometry of a desired application. In a number of embodiments, the at least one stiff and penetrable electrode shank site portion 108 may include a trace end 112′ including an electrically conductive material. The electrode body 102 may further include at least one transition portion 106 between the stiff and penetrable electrode shank site portion 108 and the flexible, stretchable ribbon cable portion 104, the at least one transition portion 106 having a length, L_{TP}, along at least a portion of the length, L_{E}, of the electrode body 102. The at least one transition portion 106 can be configured in conformance with overall interconnect geometry of a desired application.

In a number of embodiments, the flexible, stretchable ribbon cable portion 104 may be stretchable, due to the compositional layers of the section as described in further detail below, to at least 150% of its length down the central longitudinal (x) axis 150, such as at least 170%, such as at least 190%, such as at least 200%, such as at least 210%, or such as at least 220% of its length, L_{RC}, down the central longitudinal (x) axis 150 while maintaining an electrical connection (e.g. resistance, impedance) along its length, L_{RC}, when stretched. In a number of embodiments, the flexible, stretchable ribbon cable portion 104 may be bendable, due to the compositional layers of the section as described in further detail below, about a radius of less than 1.2 mm while maintaining an electrical connection (e.g. resistance, impedance) along its length, L_{RC}, when bent. Additional testing will be done on the mechanism of bending and stretching the electrode 100 according to embodiments herein while maintaining an electrical connection.

The electrically conductive material of the flexible, stretchable ribbon cable portion 104 and the stiff and penetrable electrode shank site portion 108 can each comprise one or more layers of materials. Electrically conductive materials useful for the at least one flexible, stretchable ribbon cable portions 104, 104′ include metallic conducting materials such as copper, silver, gold, aluminum and the like. Alternatively, the electrically conductive material may include organic conducting materials such as polyaniline. Suitable electrically conductive materials may include a semiconductor, either inorganic like silicon or indium tin oxide, or organic-like pentacene or polythiophene. Alternatively, electrically conductive materials can be alloys instead of stoichiometric elements or compounds. In an embodiment, the electrically conductive material of the flexible, stretchable ribbon cable portion 104 may have the same composition as the electrically conductive material of the stiff and penetrable electrode shank site portion 108. Alternatively, in an embodiment, the electrically conductive material of the flexible, stretchable ribbon cable portion 104 may have a different composition as the electrically conductive material of the stiff and penetrable electrode shank site portion 108.

Still referring to FIGS. 1A-1B, the flexible, stretchable ribbon cable portion 104 of the electrode body 102 may further include at least one pad 110 on at least one axial end 102a, 102b of the electrode body 102 down the central longitudinal (x) axis 150. The at least one pad 110 may be located on the flexible, stretchable ribbon cable portion 104. The at least one pad 110 may include at least one trace end 112 on the distal end 102a for electrically connecting the electrode 100 to a neighboring component. In a number of embodiments, the at least one pad 110 may include a plurality of trace ends 112 for electrically connecting the electrode 100 to a neighboring component. In a number of embodiments, as shown in FIG. 3, a plurality of pads 110 may each include a trace end 112 for electrically connecting the electrode 100 to a neighboring component.

Still referring to FIGS. 1A-1B, the stiff and penetrable electrode shank site portion 108 of the electrode body 102 may further include at least one shank site 114 on at least one axial end 102a, 102b of the electrode body 102 down the central longitudinal (x) axis 150. The at least one shank site 114 may be located on the stiff and penetrable electrode shank site portion 108. The at least one shank site 114 may include at least one trace end 112′ on the proximal end 102b for electrically connecting the electrode 100 to a neighboring component. In a number of embodiments, the at least one shank site 114 may include a plurality of trace ends 112′ for electrically connecting the electrode 100 to a neighboring component. In a number of embodiments, as shown in FIG. 3, a plurality of shank sites 114 may each include a trace end 112′ for electrically connecting the electrode 100 to a neighboring component. As shown in FIGS. 1A-1B and 3, the at least one shank site 114 may be offset from the at least one pad 110 about a central longitudinal (x) axis 150. In a number of embodiments, the at least one trace end 112′ of the at least one shank site 114 may be electrically connected to the at least one trace end 112 of the at least one flexible, stretchable ribbon cable portion 104 through the at least one transition portion 106.

Referring now to FIGS. 4-1 to 4-9, a method of fabrication for the electrode 100 is shown as described above. The method of fabrication can include a series of procedural steps in which various layers are deposited or removed (e.g., etched) to achieve a final form as shown in FIGS. 4-1 to 4-9. In some embodiments, etching of the layers may be performed in a plasma etcher such as a Reactive Ion Etcher. In some embodiments, etching of the layers may be performed with chlorine gas. In some embodiments, etching of the layers may be performed with electrochemical etching. After the etching process is finished, any of the layers can be removed using a solvent.

As shown best in FIG. 4-1, the method of fabrication for the electrode 100 may include a step of providing a substrate 114 having a length down a central longitudinal (x) axis 150. The substrate 114 may include a first polymer layer 116. The substrate 114 may be coated to have an initial thickness of about 4 μm. The substrate 114 may then be at least partially etched to have a non-uniform thickness as shown. In a number of embodiments, the subsequently etched substrate 114 may have a thickness of between about 1.5 μm and about 4 μm along its length down the central longitudinal (x) axis 150.

In one aspect of the present invention, the substrate 114 can be an organic or inorganic material. In one aspect of the present invention, the substrate 114 can be an elastomeric material including carbon-based or silicon-based polymeric rubbers. Suitable elastomeric materials are silicone rubber, such as polydimethyl siloxane (PDMS) and acrylic rubber. In one aspect of the present invention, the substrate 114 can be a plastic material including polyethylene terephthalate. Alternatively, in one aspect of the present invention, the substrate 114 can be a polymeric material. A suitable polymeric material is polyimide. Geometry of substrate 114 can be determined for a desired use. For example, substrate 114 can have a thickness of less than about 1 m to about 1 cm and an area in the range of about 1 μm² to about 1 μm² or more. The substrate 114 may be deposited to have an initial thickness of about 4 μm. Subsequently, the substrate 114 may then be at least partially etched to have a non-uniform thickness as shown. In a number of embodiments, the substrate 114 may have a thickness of between about 0.1 μm and about 4 μm along its length down the central longitudinal (x) axis 150.

As shown best in FIG. 4-2, the method of fabrication for the electrode 100 may include a step of depositing a first ceramic layer 118 upon the substrate 114. The deposition step may be done via electron beam evaporation, thermal evaporation, sputter deposition, chemical vapor deposition (CVD), electroplating, molecular beam epitaxy (MBE) or any other conventional means. In a number of embodiments, the deposition step may be done via Plasma-enhanced chemical vapor deposition (PECVD). In a number of embodiments, the first ceramic layer 118 may include a silicon carbide. The first ceramic layer 118 may be deposited to have an initial thickness of about 3 μm. Subsequently, as shown best in FIG. 4-3, the first ceramic layer 118 may then be at least partially etched to have a non-uniform thickness as shown. In a number of embodiments, the subsequently etched first ceramic layer 118 may have a thickness of between about 0.5 μm and about 3 μm along its length down the central longitudinal (x) axis 150.

As shown best in FIG. 4-4, the method of fabrication for the electrode 100 may include a step of depositing a conductive material layer 120 on the first ceramic layer 118. The deposition step may be done via metal patterning using a photolithography process and metal deposition or any other conventional means. In a number of embodiments, the conductive material layer 120 may include an electrically conductive material such as those recited herein. The conductive material layer 120 may be deposited to have an initial thickness of between about 0.01 and about 0.5 μm.

As shown best in FIG. 4-5, the method of fabrication for the electrode 100 may include a step of depositing a second ceramic layer 122 upon the conductive material layer 120. The deposition step may be done via electron beam evaporation, thermal evaporation, sputter deposition, chemical vapor deposition (CVD), electroplating, molecular beam epitaxy (MBE) or any other conventional means. In a number of embodiments, the deposition step may be done via Plasma-enhanced chemical vapor deposition (PECVD). In a number of embodiments, the second ceramic layer 122 may include a silicon carbide. The second ceramic layer 122 may be deposited to have an initial thickness of about 3 μm. Subsequently, as shown best in FIG. 4-5, the second ceramic layer 122 may then be at least partially etched to have a non-uniform thickness as shown. In a number of embodiments, the subsequently etched second ceramic layer 122 may have a thickness of between about 0.1 μm and about 3 μm along its length down the central longitudinal (x) axis 150.

As shown best in FIG. 4-6, the method of fabrication for the electrode 100 may include a step of providing a second polymer layer 124. The second polymer layer 124 may be coated to have an initial thickness of about 4 μm. The substrate 114 may then be at least partially etched to have a non-uniform thickness as shown. In a number of embodiments, the subsequently etched substrate 114 may have a thickness of between about 1.5 μm and about 4 μm along its length down the central longitudinal (x) axis 150.

In one aspect of the present invention, the second polymer layer 124 can be an organic or inorganic material. In one aspect of the present invention, the second polymer layer 124 can be an elastomeric material including carbon-based or silicon-based polymeric rubbers. Suitable elastomeric materials are silicone rubber, such as polydimethyl siloxane (PDMS) and acrylic rubber. In one aspect of the present invention, the second polymer layer 124 can be a plastic material including polyethylene terephthalate. Alternatively, in one aspect of the present invention, the second polymer layer 124 can be a polymeric material. A suitable polymeric material is polyimide. Geometry of second polymer layer 124 can be determined for a desired use. For example, second polymer layer 124 can have a thickness of less than about 0.1 m to about 1 cm and an area in the range of about 1 μm² to about 1 m² or more. The second polymer layer 124 may be deposited to have an initial thickness of about 6 μm. Subsequently, the second polymer layer 124 may then be at least partially etched to have a non-uniform thickness as shown. In a number of embodiments, the second polymer layer 124 may have a thickness of between about 0.1 μm and about 6 μm along its length down the central longitudinal (x) axis 150.

As shown best in FIGS. 4-7 and 4-8, the method of fabrication for the electrode 100 may include a step of etching the second polymer layer 124 and the second ceramic layer 122 to expose the conductive material layer 120 at the distal end 102a and the proximal end 102b. In an embodiment, the second polymer layer 124 and the second ceramic layer 122 may be selectively etched to form the at least one pad 110 and the at least one shank site 114.

As shown best in FIG. 4-9, the method of fabrication for the electrode 100 may include a step of patterning the conductive material layer 120 at the distal end 102a (forming a trace 112) and the proximal end 102b (forming a trace 112′). Additional conductive material may be further deposited via sputtering and/or metal patterning using a photolithography process and metal deposition or any other conventional means. A lift-off process may follow. Lastly a metal oxide layer 126 may be deposited over the conductive material layer 120 at the proximal end 102b. The metal oxide layer 126 may include any metal oxide known in the art. In an embodiment, the metal oxide layer may include iridium oxide.

As a result of the method of fabrication, the electrode 100, as shown best in FIGS. 1A-1B may have a flexible, stretchable ribbon cable portion 104 with thicknesses as follows: a substrate 114 comprising a first polymer layer 116 having a thickness of between 0.1 and 4 μm, a first ceramic layer 118 overlying the first polymer layer 116 and having a thickness of between 0.01 and 0.5 μm, a conductive material layer 120 overlying the first ceramic layer 118 and having a thickness of between 0.01 and 0.5 μm, and a second polymer layer 124 overlying the first ceramic layer 118 and having a thickness of between 0.1 and 6 μm, wherein the conductive material layer 120 may be exposed for electrical connection to a neighboring component. The thicknesses of the layers at this distal end 102a may allow for the ribbon cable portion 104 to be flexible and stretchable.

As a result of the method of fabrication, the electrode 100, as shown best in FIGS. 1A-1B may have a the transition portion 106 with thicknesses as follows: a substrate 114 comprising a first polymer layer 116 having a thickness of between 0.1 and 4 μm, a first ceramic layer 118 overlying the first polymer layer 116 and having a thickness of between 0.01 and 0.5 μm, a conductive material layer 120 overlying the first ceramic layer 118 and having a thickness of between 0.01 and 0.5 μm, a second ceramic layer 122 overlying the conductive material layer and having a thickness of between 0.01 and 3 μm, and a second polymer layer 124 overlying the second ceramic layer and having a thickness of between 0.1 and 6 μm.

As a result of the method of fabrication, the electrode 100, as shown best in FIGS. 1A-1B may have a stiff and penetrable electrode shank site portion 108 with thicknesses as follows: portion a substrate 114 comprising a first polymer layer 116 having a thickness of between 0.1 and 1.5 μm, a first ceramic layer 118 overlying the first polymer layer 116 and having a thickness of between 0.01 and 3 μm, a conductive material layer 120 overlying the first polymer layer and having a thickness of between 0.01 and 5 μm, and a metal oxide layer 126 overlying the conductive material layer 120 and having a thickness of between 0.01 and 5 μm, wherein at least one of the metal oxide layer or the conductive material layer is exposed for electrical connection to a neighboring component. The thicknesses of the layers at this proximal end 102b may allow for the electrode shank site portion 108 to be stiff and penetrable.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the embodiments as listed below.

Embodiment 1: An electrode comprising: an electrode body comprising a length down a central axis, wherein the electrode body comprises a flexible, stretchable ribbon cable portion comprising at least one trace comprising a conductive material, at least one stiff and penetrable electrode shank site portion comprising at least one trace comprising a conductive material, and a transition portion between the ribbon cable portion and the at least one stiff and penetrable electrode shank site portion.

Embodiment 2: A method for fabricating an electrode, the method comprising: providing a substrate comprising a length down a central axis, wherein the substrate comprises a first polymer layer, wherein the substrate has a non-uniform thickness; depositing a first ceramic layer upon the substrate, wherein the first ceramic layer has a non-uniform thickness; depositing a conductive material layer upon the first ceramic layer; depositing a second ceramic layer upon the conductive material layer, wherein the second ceramic layer has a non-uniform thickness; depositing a second polymer layer upon the second ceramic layer, wherein the second polymer layer has a non-uniform thickness; etching the second polymer layer to form an electrode shank site portion and an electrode trace site; and depositing a metal oxide layer upon the electrode shank site portion to form an electrode body comprising a flexible, stretchable ribbon cable portion comprising at least one trace comprising a conductive material, at least one stiff and penetrable electrode shank site portion comprising at least one trace comprising a conductive material, and a transition portion between the ribbon cable portion and the at least one stiff and penetrable electrode shank site portion.

Embodiment 3: The electrode of embodiment 1, wherein the electrode body comprises a substrate.

Embodiment 4: The electrode of embodiment 3, wherein the substrate comprises a first polymer layer.

Embodiment 5: The electrode of embodiment 4, wherein the first polymer layer comprises polyimide.

Embodiment 6: The electrode of embodiment 3, wherein the electrode body comprises a first ceramic layer deposited upon the substrate.

Embodiment 7: The electrode of embodiment 6, wherein the first ceramic layer comprises a silicon carbide.

Embodiment 8: The electrode of embodiment 6, wherein the electrode body comprises a conductive material layer deposited upon the first ceramic layer.

Embodiment 9: The electrode of embodiment 8, wherein the conductive material layer comprises the conductive material selected from the group comprising at least one of copper, silver, gold and aluminum.

Embodiment 10: The electrode of embodiment 8, wherein the electrode body comprises a second ceramic layer deposited upon the conductive material layer.

Embodiment 11: The electrode of embodiment 10, wherein the second ceramic layer comprises a silicon carbide.

Embodiment 12: The electrode of embodiment 10, wherein the electrode body comprises a second polymer layer deposited upon the second ceramic layer.

Embodiment 13: The electrode of embodiment 12, wherein the second polymer layer comprises polyimide.

Embodiment 14: The electrode of embodiment 1, wherein the ribbon cable portion comprises a substrate comprising a first polymer layer having a thickness of between 0.1 and 4 μm, a first ceramic layer overlying the first polymer layer and having a thickness of between 0.01 and 0.5 μm, a conductive material layer overlying the first ceramic layer and having a thickness of between 0.01 and 0.5 μm, and a second polymer layer overlying the first ceramic layer and having a thickness of between 0.1 and 6 μm, wherein the conductive material layer is exposed for electrical connection to a neighboring component.

Embodiment 15: The electrode of embodiment 1, wherein the transition portion comprises a substrate comprising a first polymer layer having a thickness of between 0.1 and 4 μm, a first ceramic layer overlying the first polymer layer and having a thickness of between 0.01 and 0.5 μm, a conductive material layer overlying the first ceramic layer and having a thickness of between 0.01 and 0.5 μm, a second ceramic layer overlying the conductive material layer and having a thickness of between 0.01 and 3 μm, and a second polymer layer overlying the second ceramic layer and having a thickness of between 0.1 and 6 μm.

Embodiment 16: The electrode of embodiment 1, wherein the electrode shank site portion comprises a substrate comprising a first polymer layer having a thickness of between 0.1 and 1.5 μm, a first ceramic layer overlying the first polymer layer and having a thickness of between 0.01 and 3 μm, a conductive material layer overlying the first polymer layer and having a thickness of between 0.01 and 5 μm, and a metal oxide layer overlying the conductive material layer and having a thickness of between 0.01 and 5 μm, wherein at least one of the metal oxide layer or the conductive material layer is exposed for electrical connection to a neighboring component.

Embodiment 17: The electrode of embodiment 16, wherein the metal oxide layer comprises iridium oxide.

Embodiment 18: The electrode of embodiment 1, wherein the ribbon cable portion is stretchable to at least 150% of its length down the central longitudinal (x) axis, such as at least 170%, such as at least 190%, such as at least 200%, such as at least 210%, or such as at least 220% of its length down the central axis.

Embodiment 19: The electrode of embodiment 18, wherein the ribbon cable portion maintains an electrical connection along its length when stretched.

Embodiment 20: The electrode of embodiment 1, wherein the ribbon cable portion is bendable about a radius of less than 1.2 mm while maintaining an electrical connection along its length when bent.

Embodiment 21: The electrode of embodiment 1, wherein the stiff and penetrable electrode shank site portion further comprises at least one shank site comprising the at least one trace on a proximal end of the electrode body down the central axis.

Embodiment 22: The electrode of embodiment 21, wherein the at least one trace allows for electrically connecting the electrode to a neighboring component.

Embodiment 23: The electrode of embodiment 1, wherein the ribbon cable portion further comprises at least one pad comprising the at least one trace on a distal end of the electrode body down the central axis.

Embodiment 24: The electrode of embodiment 23, wherein the at least one trace allows for electrically connecting the electrode to a neighboring component.

Embodiment 25: The electrode of embodiment 1, wherein the ribbon cable is implantable upon a biological substrate.

Note that not all of the features described above are required, that a portion of a specific feature may not be required, and that one or more features may be provided in addition to those described. Still further, the order in which features are described is not necessarily the order in which the features are installed.

Certain features are, for clarity, described herein in the context of separate embodiments, may also be provided in combination in a single embodiment. Conversely, various features that are, for brevity, described in the context of a single embodiment, may also be provided separately or in any subcombinations.

Benefits, other advantages, and solutions to problems have been described above with regard to specific embodiments, however, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or any change may be made without departing from the scope of the disclosure. Accordingly, the disclosure is to be regarded as illustrative rather than restrictive.

What is claimed is:

1. An electrode comprising:
an electrode body comprising a length down a central axis, wherein the electrode body comprises a flexible, stretchable ribbon cable portion comprising at least one trace comprising a conductive material, at least one stiff and penetrable electrode shank site portion comprising at least one trace comprising a conductive material, and a transition portion between the ribbon cable portion and the at least one stiff and penetrable electrode shank site portion.

2. A method for fabricating an electrode, the method comprising:
providing a substrate comprising a length down a central axis, wherein the substrate comprises a first polymer layer, wherein the substrate has a non-uniform thickness;
depositing a first ceramic layer upon the substrate, wherein the first ceramic layer has a non-uniform thickness;
depositing a conductive material layer upon the first ceramic layer;
depositing a second ceramic layer upon the conductive material layer, wherein the second ceramic layer has a non-uniform thickness;
depositing a second polymer layer upon the second ceramic layer, wherein the second polymer layer has a non-uniform thickness;
etching the second polymer layer to form an electrode shank site portion and an electrode trace site; and
depositing a metal oxide layer upon the electrode shank site portion to form an electrode body comprising a flexible, stretchable ribbon cable portion comprising at least one trace comprising a conductive material, at least one stiff and penetrable electrode shank site portion comprising at least one trace comprising a conductive material, and a transition portion between the ribbon cable portion and the at least one stiff and penetrable electrode shank site portion.

3. The electrode of claim 1, wherein the electrode body comprises a substrate.

4. The electrode of claim 3, wherein the substrate comprises a first polymer layer.

5. The electrode of claim 4, wherein the first polymer layer comprises polyimide.

6. The electrode of claim 3, wherein the electrode body comprises a first ceramic layer deposited upon the substrate.

7. The electrode of claim 6, wherein the first ceramic layer comprises a silicon carbide.

8. The electrode of claim 6, wherein the electrode body comprises a conductive material layer deposited upon the first ceramic layer.

9. The electrode of claim 8, wherein the conductive material layer comprises the conductive material selected from the group comprising at least one of copper, silver, gold and aluminum.

10. The electrode of claim 8, wherein the electrode body comprises a second ceramic layer deposited upon the conductive material layer.

11. The electrode of claim 10, wherein the second ceramic layer comprises a silicon carbide.

12. The electrode of claim 10, wherein the electrode body comprises a second polymer layer deposited upon the second ceramic layer.

13. The electrode of claim 12, wherein the second polymer layer comprises polyimide.

14. The electrode of claim 1, wherein the ribbon cable portion comprises a substrate comprising a first polymer layer having a thickness of between 0.1 and 4 μm, a first ceramic layer overlying the first polymer layer and having a thickness of between 0.01 and 0.5 μm, a conductive material layer overlying the first ceramic layer and having a thickness of between 0.01 and 0.5 μm, and a second polymer layer overlying the first ceramic layer and having a thickness of between 0.1 and 6 μm, wherein the conductive material layer is exposed for electrical connection to a neighboring component.

15. The electrode of claim 1, wherein the transition portion comprises a substrate comprising a first polymer layer having a thickness of between 0.1 and 4 μm, a first ceramic layer overlying the first polymer layer and having a thickness of between 0.01 and 0.5 μm, a conductive material layer overlying the first ceramic layer and having a thickness of between 0.01 and 0.5 μm, a second ceramic layer overlying the conductive material layer and having a thickness of between 0.01 and 3 μm, and a second polymer layer overlying the second ceramic layer and having a thickness of between 0.1 and 6 μm.

16. The electrode of claim 1, wherein the electrode shank site portion comprises a substrate comprising a first polymer layer having a thickness of between 0.1 and 1.5 μm, a first ceramic layer overlying the first polymer layer and having a thickness of between 0.01 and 3 μm, a conductive material layer overlying the first polymer layer and having a thickness of between 0.01 and 5 μm, and a metal oxide layer overlying the conductive material layer and having a thickness of between 0.01 and 5 μm, wherein at least one of the metal oxide layer or the conductive material layer is exposed for electrical connection to a neighboring component.

17. The electrode of claim 16, wherein the metal oxide layer comprises iridium oxide.

18. The electrode of claim 1, wherein the ribbon cable portion is stretchable to at least 150% of its length down the central longitudinal (x) axis, such as at least 170%, such as at least 190%, such as at least 200%, such as at least 210%, or such as at least 220% of its length down the central axis.

19. The electrode of claim 18, wherein the ribbon cable portion maintains an electrical connection along its length when stretched.

20. The electrode of claim 1, wherein the ribbon cable portion is bendable about a radius of less than 1.2 mm while maintaining an electrical connection along its length when bent.
